(19) United States
(12) Patent Application Publication
(10) Pub. No.: US 2006/0060139 A1
(43) Pub. Date: Mar. 23, 2006

(54) Precursor gas delivery with carrier gas mixing

(75) Inventors: Paul Meneghini, Haverhill, MA (US); Daniel Smith, North Andover, MA (US); Ali Shajii, Canton, MA (US)

Correspondence Address: MCDERMOTT WILL & EMERY LLP;ATTN: INTELLECTUAL PROPERTY DEPTARTMENT DOCKETING, 28 STATE STREET, BOSTON, MA, 02109, US

(73) Assignee: MKS Instruments, Inc., Wilmington, MA (US)

(21) Appl. No.: 11/223,366

(22) Filed: Sep. 9, 2005

Related U.S. Application Data
(63) Continuation-in-part of application No. 10/822,358, filed on Apr. 12, 2004.
(63) Continuation-in-part of application No. 11/015,465, filed on Dec. 17, 2004.
(63) Continuation-in-part of application No. 11/083,586, filed on Mar. 18, 2005.

(51) Int. Cl. C23C 16/00

(52) U.S. Cl. 118/715

(57) ABSTRACT

A system and method are described that control the amount of precursor that is delivered to a process chamber by precisely measuring the mole fraction of the gas mixture being delivered. A gas delivery system includes a delivery chamber, a precursor inlet valve, a carrier inlet valve, an outlet valve, and a controller. The controller controls the opening and closing of the precursor inlet valve, the carrier inlet valve, and the outlet valve, so as to introduce a desired amount of a precursor gas and a carrier gas into the delivery chamber, to generate a gas mixture having a desired mole fraction of the precursor gas, and to deliver to the process chamber the gas mixture having the desired mole fraction of the precursor gas.

### CROSS-REFERENCE TO RELATED APPLICATIONS

The present application is a continuation in part of, and claims priority to, the following U.S. patent applications: co-pending application Ser. No. 10/822,358 (the “'358 application”), filed on Apr. 12, 2004 (attorney docket number MKS-143); co-pending application Ser. No. 11/015,465 (the “'465 application”), filed on Dec. 17, 2004 (attorney docket number MKS-147); and co-pending application Ser. No. 11/083,586 (the “'586 application”), filed on Mar. 18, 2005 (attorney docket number MKS-156).

All these co-pending patent applications are assigned to the assignee of the present application. The content of all of these co-pending patent applications is incorporated herein by reference, as though fully set forth herein.

### BACKGROUND

Semiconductor fabrication may require carefully synchronized and precisely measured delivery of reactant gases to semiconductor process chambers. Systems and methods for delivering highly repeatable and precise quantities of gaseous mass may therefore be useful in a number of semiconductor manufacturing processes, including but not limited to atomic layer deposition (ALD) processes.

In general, when a precursor gas is being delivered to a process chamber, pressure may be the driving force. For some precursor gases, the saturated vapor pressure may be too low to allow for effective delivery of the gas. In this case, a carrier gas that is inert to the process chemistry may be introduced, to artificially increase the pressure. The precursor gas will not condense, as long as the partial pressure of the precursor is below its saturated vapor pressure and the carrier gas is uniformly mixed with the precursor.

Previous techniques for delivering low vapor pressure precursors may include the use of bubbler systems. In a bubbler system, the carrier gas may be introduced by bubbling it through the liquid precursor. During this process, some molecules of the liquid precursor may become absorbed into the carrier gas. The resulting mixture may have a much higher pressure, compared to the partial pressure of the precursor alone, and may thus facilitate delivery to a process chamber.

The concentration of the precursor in the mixture that comes from a bubbler system is not known, however, and may be difficult to measure accurately. Since the concentration of the precursor in the mixture is not known, the amount of precursor delivered to the delivery chamber also may not be known.

For these reasons, a method and system are desired for accurately and repeatably delivering precise amounts of precursors, including low vapor pressure precursors.

### SUMMARY

A gas delivery system may include a delivery chamber, a precursor inlet valve, a carrier inlet valve, an outlet valve, and a controller. The precursor inlet valve is configured to regulate the flow of a precursor gas into the delivery chamber. The carrier inlet valve is configured to regulate the flow of a carrier gas into the delivery chamber. The outlet valve is configured to regulate the flow of a mixture of the precursor gas and the carrier gas, out of the delivery chamber into a process chamber.

The controller may be configured to control the opening and the closing of the precursor inlet valve and the carrier inlet valve, so as to introduce desired amounts of the precursor gas and the carrier gas into the delivery chamber, and to generate a gas mixture having a predetermined ratio of the precursor gas to the carrier gas. The controller may be further configured to control the opening and the closing of the outlet valve so as to deliver the gas mixture having the predetermined ratio, from the delivery chamber into the process chamber.

A method of delivering a precursor gas is described. A desired number of moles of the precursor gas are introduced into a delivery chamber. Subsequently, a desired number of moles of a carrier gas are introduced into the delivery chamber. A gas mixture is thus generated, and is delivered from the delivery chamber to the process chamber. The gas mixture has a predetermined ratio of the precursor gas to the carrier gas. A desired mole fraction of the precursor gas is thus delivered to the process chamber.

### BRIEF DESCRIPTION OF THE DRAWINGS

FIG. 1 is a schematic diagram of a gas delivery system constructed in accordance with one embodiment of the present disclosure.

FIG. 2 is a graph of the pressure within a gas holding delivery chamber, during one delivery cycle of the gas delivery system illustrated in FIG. 1.

### DETAILED DESCRIPTION

A system and method are described for controlling the amount of precursor that is delivered to the process chamber, by precisely measuring the mole fraction of the gas mixture that is delivered. The technique that is described below is useful in applications that include, but are not limited to: 1) delivery of precursors with very low vapor pressure; and 2) delivery of extremely small amounts of precursor with greater accuracy.

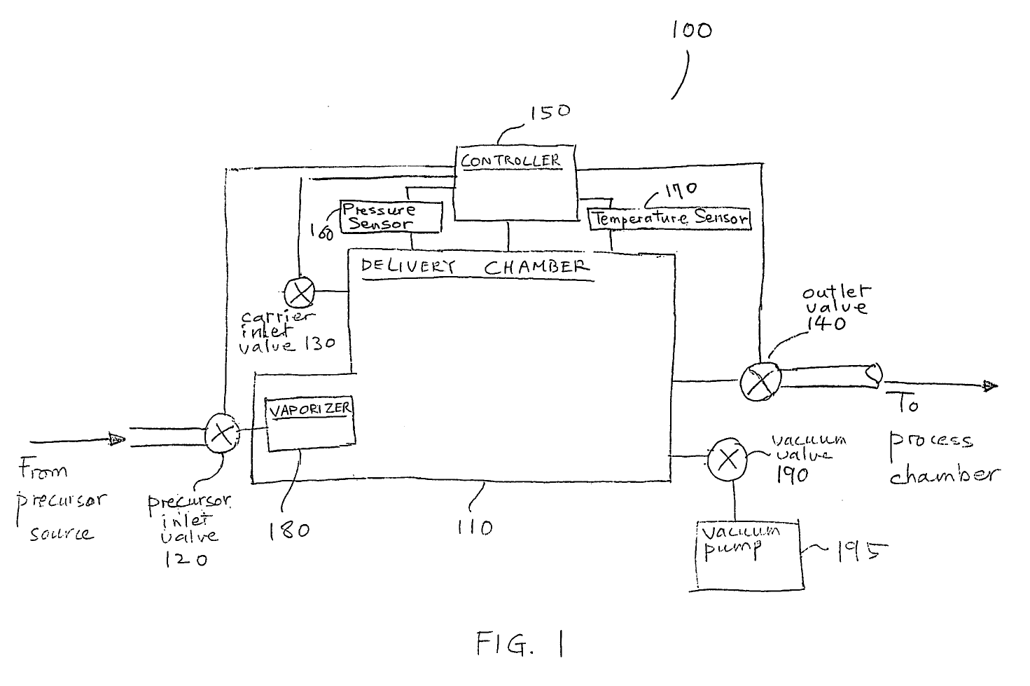

FIG. 1 is a schematic diagram of a gas delivery system 100, constructed in accordance with one embodiment of the present disclosure. The gas delivery system 100 is configured to vaporize a precursor into a known volume, and then deliver the precursor into an output chamber. The output chamber may be a semiconductor process chamber, for example. The gas delivery system 100 implements model-based algorithms, in order to accurately measure and control the number of molecules of the precursor gas it delivers to the process chamber.

In overview, the gas delivery system 100 includes: a delivery chamber 110; a precursor inlet valve 120; a carrier inlet valve 130; an outlet valve 140; a controller 150; a pressure sensor 160; a temperature sensor 170; a vaporizer 180; a vacuum inlet valve 190; and a vacuum pump 195. The delivery chamber 110 provides a calibrated holding volume for the gases being delivered. The precursor inlet valve 120 is configured to regulate the flow of one or more precursor gases into the delivery chamber 110. In the illustrated embodiment, the vaporizer 180 vaporizes a liquid precursor, which may be supplied by a liquid precursor source (not shown), to generate the precursor vapor.

The carrier inlet valve 130 is configured to regulate the flow of one or more carrier gases into the delivery chamber 110. The outlet valve 140 is configured to regulate the flow of a mixture of the precursor gas and the carrier gas out of the delivery chamber 110 and into the process chamber (not shown). The gas mixture that is delivered has a known, predetermined ratio of the precursor gas to the carrier gas. The pressure sensor 160 is configured to measure the pressure within the delivery chamber 110, and the temperature sensor 170 is configured to measure the temperature in the delivery chamber 110.

The controller 150 is programmed to control the opening and closing of the precursor inlet valve 120, the carrier inlet valve 130, and the outlet valve 140, so as to deliver from the delivery chamber 110 into the process chamber the gas mixture, which has a precise, known mole fraction of the precursor gas to the carrier gas.

The controller 150 may implement the methods, systems, and algorithms described in the present disclosure, using computer software. The methods and systems in the present disclosure are not described with reference to any particular programming language. It will be appreciated that a variety of programming languages may be used to implement the teachings of the present disclosure. The controller 150 may be selectively configured and/or activated by a computer program stored in the computer.

The controller 150 first controls the opening and closing of the precursor inlet valve 120 so as to introduce the desired amount of the precursor gas into the delivery chamber 110. Subsequently, the controller 150 controls the opening and closing of the carrier inlet valve 130 to introduce a precise, desired amount of the carrier gas into the delivery chamber 110. Finally, the controller 150 controls the opening and closing of the outlet valve 140, so as to cause the gas mixture (having the known mole fraction of the precursor gas) to be formed by diffusion in the delivery chamber 110, and to cause the gas mixture to be delivered from the delivery chamber 110 to the process chamber.

The controller 150 is configured to count the number of moles of precursor gas that leaves the delivery chamber 110 while discharging to the process chamber. In particular, the controller 150 is programmed to monitor the pressure measurements by the pressure sensor 160 and the temperature measurements by the temperature sensor 170, and to use the ideal gas law to derive the desired number of moles.

Typically the delivery system 100 is a pulsed delivery system configured to deliver the precursor gas in a sequence of delivery pulses. In overview, the delivery system 100 delivers the precursor in discrete pulses according to the following cycle:

1. Charge:

Open the precursor inlet valve 120, and vaporize the precursor into the delivery chamber volume, charging it to a target pressure. Wait for a brief period, for the pressure to stabilize.

2. Deliver:

Open the outlet valve 140, which is connected to the process chamber. Measure the amount of precursor delivered, and close the outlet valve 140 when the correct amount of precursor has left the delivery chamber 110.

3. Wait for the pressure to stabilize.

4. Proceed to the next cycle, in which steps 1, 2, and 3 above are repeated.

The controller 150 of the gas delivery system 100 uses model-based algorithms to measure and control the number of moles of precursor that is vaporized into the holding volume of the delivery chamber 110, in step 1 above. The controller 150 uses these algorithms to measure and control the number of moles of carrier gas that is subsequently added to the holding volume provided by the delivery chamber 110.

Unlike gas delivery systems in which the carrier gas is introduced without knowing the respective amounts of the precursor gas and the carrier gas, the algorithms implemented by the controller 150 allow the number of moles of each species to be counted, as they are being mixed. In the gas delivery system 100 above, therefore, the mole fraction of each species (precursor or carrier) in the resulting mixture in the delivery chamber 110 will be known before the delivery chamber 110 discharges into the process chamber.

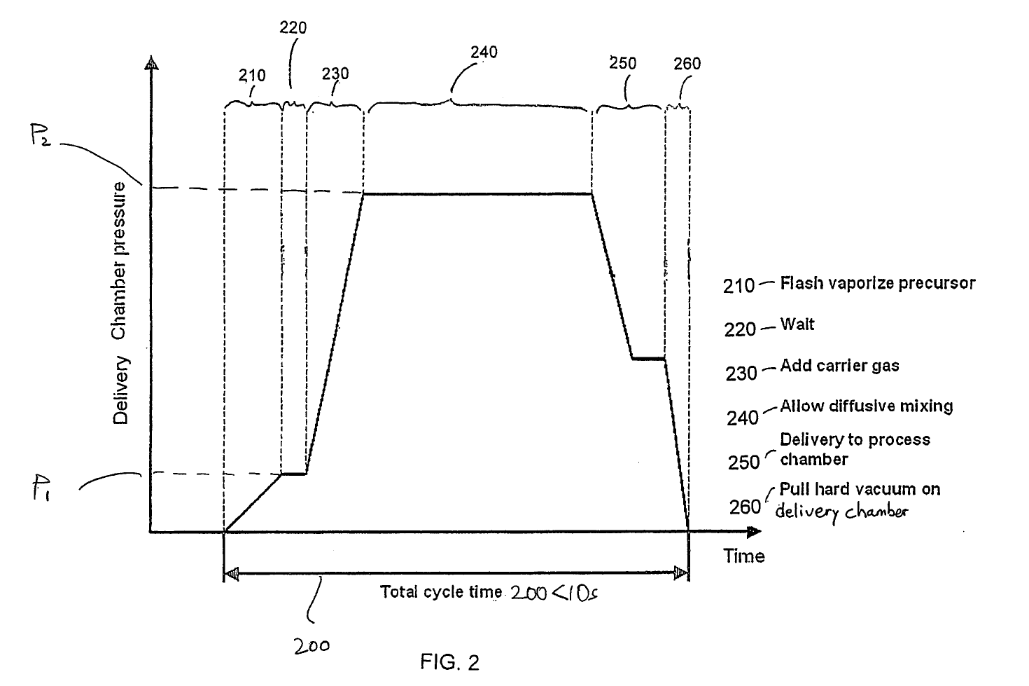

The delivery process during each cycle will now be described in more detail, in conjunction with FIG. 2. FIG. 2 is a graph of the pressure within the delivery chamber 110 as a function of time, during a single delivery cycle by the gas delivery system illustrated in FIG. 1. As illustrated in FIG. 2, a single delivery cycle 200 may include stages 210, 220, 230, 240, 250, and 260, in one embodiment of the present disclosure. Each of the stages occupies a time interval that consists of a respective fraction of the total cycle time 200, as shown in FIG. 2.

During stage 210, the controller 150 opens the precursor inlet valve 120 so as to introduce the precursor gas into the delivery chamber 110. The precursor gas is then flash vaporized and charged to a first target pressure, indicated in FIG. 2 as P₁. The controller 150 then measures the amount of the precursor gas that goes into the holding volume of the delivery chamber 110, and closes the precursor inlet valve 120 when a target number of moles are in the holding volume. The number of moles delivered to the delivery chamber 110 during this stage is given by:

$$Δ n = \frac{V}{R} Δ ( \frac{P}{T} ) . \qquad ( 1 )$$

In equation (1) above, Δn denotes the number of moles delivered into the delivery chamber 110, V denotes the volume of the delivery chamber 110, R denotes the universal gas constant (having a value of 8.3144 Joules/mol/K), and Δ(P/T) is the change in pressure divided by gas temperature, from the beginning of the cycle 200 to the end of the cycle 200. Equation (1) shows that, by monitoring the values of P and T, as measured by the pressure sensor 160 and the temperature sensor 170 at desired points in time, the number of moles being delivered into the delivery chamber 110 during any given time period can be monitored. The temperature dynamics within the delivery chamber 110 is described for example in the '358 application, the content of which has been incorporated by reference in its entirety.

After the target pressure P₁ is reached within the gas delivery chamber 110, the controller 150 causes the system 100 to wait for a while for the pressure to stabilize, during stage 220.

During the next stage, 230, a carrier gas is introduced, and the resulting mixture is charged to a second target pressure, shown in FIG. 2 as P₂. In particular, the controller 150 opens the carrier inlet valve 130 to the delivery chamber 110, to let the carrier gas flow in, then measures the number of moles of carrier gas that enter the holding volume of the delivery chamber 110. The controller 150 closes the carrier inlet valve 130 when the second target pressure P₂ is obtained.

During stage 240, the system 100 waits for the mixture to equilibrate. In particular, the controller 150 causes the system 100 to wait for a period of time sufficient to cause the precursor gas and the carrier gas to mix by diffusion, and to cause the gas mixture to equilibrate. The equilibrated gas mixture, at the end of the stage 240, has the desired mole fraction of the precursor gas.

At the end of stage 240, the resulting gas mixture in the delivery chamber 110 is a precursor gas/carrier gas mixture, at a user-specified pressure P₂. Because the number of moles of each substance is measured, as each substance is delivered into the holding volume of the delivery chamber 110, the mole fraction of each gas species (precursor or carrier) in the delivery chamber 110 is known. As a simple example, if 10 μmoles of precursor gas and 90 μmoles of carrier gas have been counted by the controller 150, then the gas mixture in the delivery chamber 110 has a mole fraction of 1/10 for the precursor gas, and 9/10 for the carrier gas. At this time, the partial pressure of the precursor is still below the vapor pressure of the precursor at the operating temperature. Also, there is enough of a pressure gradient between the delivery chamber 110 and the process chamber, to ensure rapid delivery.

The system 100 then moves on to the delivery stage 250, during which the equilibrated gas mixture is delivered to the process chamber. The controller 150 opens the outlet valve 140, which leads to the process chamber. The controller 150 measures the amount of the gas mixture that leaves the delivery chamber 110, and closes the outlet valve 140 when the correct desired amount of precursor gas has left the delivery chamber 110. As long as the gas is a continuum, the mole fraction of the mixture remains constant during delivery.

During the next and final stage 260, the controller 150 opens the vacuum inlet valve 190, and pulls vacuum on the delivery chamber 110, until the pressure within the delivery chamber 110 is comfortably below the vapor pressure of the precursor at the operating temperature.

Once an entire delivery cycle 200 is completed, the controller 150 causes the system 100 to return to stage 210, and repeat the entire delivery cycle, for a desired number of times. For each delivery cycle, the system 100 directly mixes the precursor gas and the carrier gas to a specific mole fraction, using the technique described above. Any residual mixture left in the delivery chamber 110 at the end of stage 260 has the same mole fraction. Therefore, the total number of moles of precursor delivered to the process chamber is given by:

$$Δ n = ω \frac{V}{R} Δ ( \frac{P}{T} ) \qquad ( 3 )$$

where the same definitions as in equation (1) above apply, and ω denotes the mole fraction of the precursor gas.

In sum, a system and method have been described that allows a gas delivery system (such as the MDD) to deliver low vapor pressure precursors with high precision. This is made possible by directly measuring and controlling the mole fractions of the gas mixture.

While certain embodiments have been described of an apparatus and method for pulsed deposition monitoring and control, it is to be understood that the concepts implicit in these embodiments may be used in other embodiments as well. The protection of this application is limited solely to the claims that now follow.

In these claims, reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference, and are intended to be encompassed by the claims. Moreover, nothing disclosed herein is intended to be dedicated to the public, regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A gas delivery system, comprising:
a delivery chamber;
a precursor inlet valve configured to regulate flow of a precursor gas into the delivery chamber;
a carrier inlet valve configured to regulate flow of a carrier gas into the delivery chamber;
an outlet valve configured to regulate flow of the precursor gas and the carrier gas out of the delivery chamber into an output chamber; and
a controller configured to control opening and closing of the precursor inlet valve, the carrier inlet valve, and the outlet valve, so as to introduce a desired amount of the precursor gas and the carrier gas into the delivery chamber, generate a gas mixture having a predetermined ratio of the precursor gas to the carrier gas, and deliver from the delivery chamber into the output chamber the gas mixture having the predetermined ratio.

2. The gas delivery system of claim 1, further comprising:
a pressure transducer configured to measure pressure within the delivery chamber; and
a temperature sensor configured to measure temperature of the precursor gas, the carrier gas, and the gas mixture.

3. The gas delivery system of claim 2,
wherein the predetermined ratio comprises a ratio between a number of moles of the precursor gas in the gas mixture, and a number of moles of the carrier gas in the gas mixture; and
wherein the gas mixture has a desired mole fraction of the precursor gas and a desired mole fraction of the carrier gas.

4. The gas delivery system of claim 3, wherein the controller is further configured to measure a number of moles of the precursor gas that flows into the delivery chamber during a time period, by monitoring pressure measurements of the pressure transducer and temperature measurements of the temperature sensor; and
wherein the number of moles of the precursor gas delivered into the delivery chamber during the time period and occupying a volume V of the delivery chamber is given by:
$$Δ n = ω \frac{V}{R} Δ ( \frac{P}{T} ) ,$$
where Δn denotes the number of moles of the precursor gas delivered into the delivery chamber during the time period,
ω denotes a mole fraction of the precursor gas,
R denotes a universal gas constant that is a product of Boltzmann's constant and Avogadro's number and that has a value of about 8.3144 (Joules)(mol⁻¹)(K⁻¹),
P denotes pressure of the precursor gas occupying the volume V,
T denotes temperature of the precursor gas occupying the volume V, and
Δ(P/T) denotes a change in a ratio between P and T between beginning and end of the time period.

5. The gas delivery system of claim 4, wherein the controller is further configured to:
open the precursor inlet valve to allow the precursor gas to flow into the delivery chamber;
measure a number of moles of the precursor gas that flows into the delivery chamber through the precursor inlet valve by monitoring pressure measurements of the pressure transducer and temperature measurements of the temperature sensor; and
close the precursor inlet valve when a desired number of moles of the precursor gas have entered the delivery chamber.

6. The gas delivery system of claim 5, wherein the controller is further configured to:
open the carrier inlet valve after closing the precursor inlet valve, so as to cause the carrier gas to flow into the delivery chamber after the desired number of moles of the precursor gas have entered the delivery chamber,
measure a number of moles of carrier gas that flow into the delivery chamber through the carrier inlet valve by monitoring pressure measurements of the pressure transducer and temperature measurements of the temperature sensor, and
close the carrier inlet valve when said pressure measurements and temperature measurements indicate that a desired number of moles of the carrier gas have entered the delivery chamber.

7. The gas delivery system of claim 6, wherein the controller is further configured to:
wait after closing the carrier inlet valve and before opening the outlet valve, for a period of time that is sufficient to cause the precursor gas and the carrier gas to mix by diffusion and generate the gas mixture having the predetermined ratio of the precursor gas to the carrier gas, and to cause the gas mixture to equilibrate;
wherein the equilibrated gas mixture includes the desired mole fraction of the precursor gas.

8. The gas delivery system of claim 7, wherein the controller is further configured to open the outlet valve, after the gas mixture has equilibrated, to cause the equilibrated gas mixture to flow out of the delivery chamber and into the output chamber;
measure a number of moles of the gas mixture that leave the delivery chamber; and
close the outlet valve, when the desired number of moles of the gas mixture have left the delivery chamber and have been delivered into the output chamber.

9. The gas delivery system of claim 7, wherein a pressure gradient between the delivery chamber and the output chamber, after the gas mixture has equilibrated, is sufficient to allow for a relatively rapid delivery of the gas mixture from the delivery chamber into the output chamber.

10. The gas delivery system of claim 7,
wherein at an operating temperature of the gas delivery system, the precursor gas reaches vapor phase equilibrium at a precursor vapor pressure, and
wherein a desired partial pressure of the precursor gas is below the precursor vapor pressure.

11. The gas delivery system of claim 7, wherein the desired mole fraction of the precursor gas is user-specified.

12. The gas delivery system of claim 9, further comprising a vacuum inlet valve that connects the delivery chamber to a vacuum subsystem configured to pull vacuum in the delivery chamber.

13. The gas delivery system of claim 12,
wherein the controller is further configured to:
open the vacuum inlet valve after closing the outlet valve, causing the vacuum subsystem to pull vacuum in the delivery chamber; and
close the vacuum inlet valve when pressure in the delivery chamber reaches a value that is substantially below the precursor vapor pressure.

14. The gas delivery system of claim 13, further comprising a vaporizer configured to vaporize a liquid precursor to generate the precursor gas.

15. The gas delivery system of claim 14,
wherein the controller is further configured to:
open the precursor inlet valve to allow the liquid precursor to flow into the delivery chamber;
activate the vaporizer so as to vaporize the liquid precursor and generate the precursor gas;
leave the precursor inlet valve open, so that the liquid precursor continues to flow into the delivery chamber, until pressure of the vaporized precursor reaches the desired precursor pressure and quantity of the precursor gas in the delivery chamber reaches the desired number of moles; and
close the precursor inlet valve when the desired number of moles of the precursor gas has been reached.

16. The gas delivery system of claim 14, further comprising a liquid precursor source configured to provide the liquid precursor to the delivery chamber through the inlet valve.

17. The gas delivery system of claim 1, wherein the output chamber comprises a semiconductor process chamber.

18. The gas delivery system of claim 1,
wherein the controller is further configured to repeat, during each of a plurality of delivery cycles, the acts of controlling the opening and closing of the precursor inlet valve, the carrier inlet valve, and the outlet valve so as to introduce a desired amount of the precursor gas and the carrier gas into the delivery chamber, generate a gas mixture having a predetermined ratio of the precursor gas to the carrier gas, and deliver from the delivery chamber into the semiconductor process chamber the gas mixture having the predetermined ratio.

19. A method of delivering a precursor gas, the method comprising:
introducing a desired number of moles of the precursor gas into a delivery chamber;
introducing a desired number of moles of a carrier gas into the delivery chamber, after the desired number of moles of the precursor gas have entered the delivery chamber, to generate a gas mixture having a predetermined ratio of the precursor gas to the carrier gas; and
delivering the gas mixture from the delivery chamber to an output chamber, the gas mixture having a desired mole fraction of the precursor gas.

20. The method of claim 19, wherein the act of introducing the desired number of moles of the precursor gas comprises:
opening a precursor inlet valve that regulates flow of the precursor gas into the delivery chamber; and
monitoring pressure measurements by a pressure transducer while the precursor inlet valve is open, to measure a number of moles of the precursor gas that are being delivered into the delivery chamber through the precursor inlet valve.

21. The method of claim 20, wherein the act of introducing the desired number of moles of the carrier gas comprises:
opening a carrier inlet valve that regulates flow of the carrier gas into the delivery chamber; and
monitoring pressure measurements by a pressure transducer while the carrier inlet valve is open, to measure a number of moles of the carrier gas that are being delivered into the delivery chamber through the carrier inlet valve.

22. The method of claim 19, further comprising the act of vaporizing a liquid precursor in order to generate the precursor gas.
